(19) United States
(12) Patent Application Publication
(10) Pub. No.: US 2025/0279305 A1
(43) Pub. Date: Sep. 4, 2025

(54) LOADING PORT STRUCTURE, SUBSTRATE PROCESSING APPARATUS, SUBSTRATE PROCESSING METHOD AND METHOD OF MANUFACTURING SEMICONDUCTOR DEVICE

(71) Applicant: Kokusai Electric Corporation, Tokyo (JP)

(72) Inventors: Takeshi ITO, Toyama-shi (JP); Iichiro TSUCHIKURA, Toyama-shi (JP); Yukinori ABURATANI, Toyama-shi (JP)

(73) Assignee: Kokusai Electric Corporation, Tokyo (JP)

(21) Appl. No.: 19/065,159

(22) Filed: Feb. 27, 2025

(30) Foreign Application Priority Data
Mar. 1, 2024 (JP) 2024-031649

(51) Int. Cl. H01L 21/677

(52) U.S. Cl. CPC H01L 21/67775; H01L 21/67766

(57) ABSTRACT

It is possible to suppress a tilt of a substrate container when a lid of the substrate container is opened. There is provided a technique that includes: a frame separating inside and outside of a local clean environment, and including: a first surface outside the local clean environment airtightly contacting an opening of a substrate container; and an entrance for the substrate container; and a latching structure switching between an engaged state where it engages with a flange around the opening and a disengaged state where a movement of the substrate container is unrestricted in an up-down direction and in a front-rear direction. The latching structure includes: heads engaging with recesses on each side of the flange; and drivers moving the heads in a direction parallel to the first surface, the heads having a contact portion generating a pressing force for the flange against the first surface.

### CROSS-REFERENCE TO RELATED PATENT APPLICATION

This non-provisional U.S. patent application is based on and claims priority under 35 U.S.C. § 119 of Japanese Patent Application No. 2024-031649 filed on Mar. 1, 2024, in the Japanese Patent Office, the entire contents of which are hereby incorporated by reference.

### BACKGROUND

### 1. Field

A technique of the present disclosure relates to a loading port structure, a substrate processing apparatus, a substrate processing method and a method of manufacturing a semiconductor device.

### 2. Related Art

According to some related arts, as a part of a manufacturing process of a semiconductor device, a process of opening a lid of a substrate container placed on a loading port structure and transferring a substrate accommodated in the substrate container may be performed.

### SUMMARY

According to the present disclosure, there is provided a technique capable of suppressing a tilt of a substrate container when a lid of the substrate container is opened.

According to an embodiment of the present disclosure, there is provided a technique that includes: a frame constituting a part of a wall configured to separate an inside and an outside of a local clean environment, and including: a first surface provided outside the local clean environment and configured to be capable of making an airtight contact with an opening of a substrate container; and an entrance through which a substrate accommodated in the substrate container is capable of passing; and a latching structure provided adjacent to the first surface and configured to be capable of being switched between an engaged state in which the latching structure engages with a flange provided around the opening and a disengaged state in which the latching structure does not engage with the flange so that a movement of the substrate container is unrestricted in an up-down direction and in a front-rear direction, wherein the latching structure includes: a pair of heads configured to respectively engage with at least two recesses formed on each side of the flange; and a pair of drivers configured to respectively move the pair of heads in a direction substantially parallel to the first surface, wherein each of the pair of heads is provided with a contact portion configured to generate a force of pressing the flange against the first surface by transitioning the latching structure from the disengaged state to the engaged state, and wherein the contact portion includes a tapered surface.

### BRIEF DESCRIPTION OF THE DRAWINGS

FIG. 1 is a diagram schematically illustrating an exemplary perspective view of a substrate processing apparatus according to one or more embodiments of the present disclosure.

FIG. 2 is a diagram schematically illustrating a vertical cross-section of a locking structure of a loading port structure according to the embodiments of the present disclosure.

FIG. 3 is a diagram schematically illustrating an exemplary perspective view of a substrate container according to the embodiments of the present disclosure.

FIG. 4A is a diagram schematically illustrating a state in which the substrate container is fixed to a frame of the loading port structure by a latching structure according to the embodiments of the present disclosure, and FIG. 4B is a diagram schematically illustrating a state in which the substrate container is released from the frame of the loading port structure by the latching structure shown in FIG. 4A.

FIG. 5 is a diagram schematically illustrating the latching structure when viewed along a Y-axis direction of FIG. 4A.

FIG. 6 is a flow chart schematically illustrating an exemplary process flow of a substrate processing performed by the substrate processing apparatus according to the embodiments of the present disclosure.

FIG. 7A is a diagram schematically illustrating a state in which the substrate container is fixed to the frame of the loading port structure by a latching structure according to a first modified example of the present disclosure, and FIG. 7B is a diagram schematically illustrating a state in which the substrate container is released from the frame of the loading port structure by the latching structure shown in FIG. 7A.

FIG. 8A is a diagram schematically illustrating a state in which the substrate container is fixed to the frame of the loading port structure by a latching structure according to a second modified example of the present disclosure, and FIG. 8B is a diagram schematically illustrating a state in which the substrate container is released from the frame of the loading port structure by the latching structure shown in FIG. 8A.

FIG. 9 is a diagram schematically illustrating a partial cross-section of the latching structure according to the second modified example.

FIG. 10 is a diagram schematically illustrating a latching structure according to a third modified example of the present disclosure.

FIG. 11 is a diagram schematically illustrating a latching structure according to a fourth modified example of the present disclosure.

FIG. 12A is a diagram schematically illustrating a cross-section of the latching structure according to the fourth modified example, taken along a line A-A shown in FIG. 11, when the latching structure according to the fourth modified example is in contact with a flange of the substrate container, and FIG. 12B is a diagram schematically illustrating the cross-section of the latching structure according to the fourth modified example, taken along the line A-A shown in FIG. 11, when the latching structure according to the fourth modified example is released from contact with the flange of the substrate container.

### DETAILED DESCRIPTION

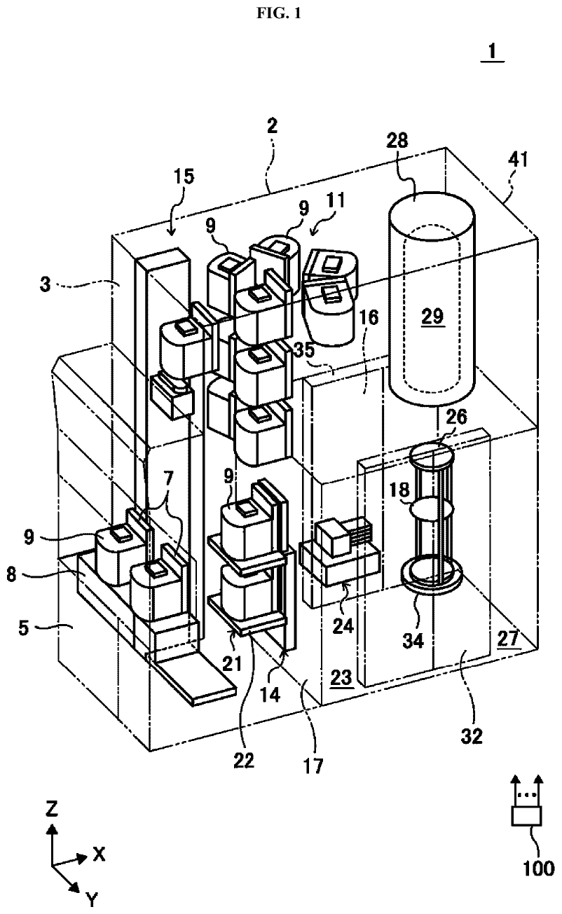

Hereinafter, one or more embodiments (also simply referred to as “embodiments”) according to the technique of the present disclosure will be described mainly with reference to FIGS. 1 to 12B. Further, the drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match. In addition, the same or similar reference numerals represent the same or similar components in the drawings. Thus, each component is described with reference to the drawing in which it first appears, and redundant descriptions related thereto will be omitted unless particularly necessary. In addition, the technique of the present disclosure is not limited to the embodiments described below. That is, the technique of the present disclosure may be modified in various ways without departing from the scope thereof.

### (1) OVERALL CONFIGURATION OF SUBSTRATE PROCESSING APPARATUS

FIG. 1 is a diagram schematically illustrating an exemplary perspective view of a substrate processing apparatus 1 according to the embodiments of the present disclosure.

For convenience of explanation, three mutually orthogonal axes (that is, an X-axis, a Y-axis, and a Z-axis) are shown in FIG. 1. The X-axis is an axis along a first direction in a horizontal direction (that is, a front-rear direction of the substrate processing apparatus 1), the Y-axis is an axis along a second direction (which is perpendicular to the X-axis) in the horizontal direction (that is, a left-right direction of the substrate processing apparatus 1), and the Z-axis is an axis along a vertical direction (that is, an up-down direction of the substrate processing apparatus 1).

As shown in FIG. 1, the substrate processing apparatus 1 includes a housing 2. An opening for performing a maintenance operation is provided at a lower portion of a front wall 3 of the housing 2. The opening can be opened or closed by a front maintenance door 5.

A pod loading/unloading port is provided at the front wall 3 of the housing 2 so as to communicate with an inside and an outside of the housing 2. The pod loading/unloading port can be opened or closed by a front shutter (which is a pod loading/unloading port opening/closing structure) 7. A pod transfer table 8 is provided in front of the pod loading/unloading port. The pod transfer table 8 is configured such that a pod 9 serving as a substrate container (also referred as a FOUP (Front Opening Unified Pod)) is aligned while placed on the pod transfer table 8.

For example, the pod 9 is configured as a sealed type substrate transfer container. A plurality of wafers 18 can be accommodated in the pod 9. Hereinafter, each of the wafers 18 may also be referred to as a “wafer 18” which serves as a substrate. The wafer 18 can be transferred while accommodated in the pod 9. For example, the pod 9 can be transferred (loaded) into and placed on the pod transfer table 8 by an in-process transfer apparatus (not shown) and can be transferred (unloaded) from the pod transfer table 8 by the in-process transfer apparatus.

A rotatable pod shelf (which is a pod storage shelf) 11 is provided in the housing 2 to be located over a substantially center portion of the housing 2 in an X-axis direction. The rotatable pod shelf 11 is configured such that a plurality of pods including the pod 9 can be stored (or placed) on the rotatable pod shelf 11. Hereinafter, the plurality of pods including the pod 9 may also be simply referred to as “pods 9”.

A pod opener (which is a pod lid attaching/detaching structure) 14 is provided below the rotatable pod shelf 11. The pod opener 14 is provided with a configuration capable of attaching and detaching a lid of the pod 9.

A pod transfer structure (which is a container transfer structure) 15 is provided among the pod transfer table 8, the rotatable pod shelf 11 and the pod opener 14. The pod transfer structure 15 is configured such that the pod 9 can be elevated and lowered in a Z-axis direction (also referred to as the “up-down direction”) while being supported by the pod transfer structure 15, and can be moved forward and backward in the horizontal direction (that is, in a Y-axis direction (also referred to as the “left-right direction”) and the X-axis direction (also referred to as the “front-rear direction”)) while being supported by the pod transfer structure 15. The pod transfer structure 15 is further configured such that the pod 9 can be transferred among the pod transfer table 8, the rotatable pod shelf 11 and the pod opener 14.

A sub-housing 16 is provided below the substantially center portion of the housing 2 in the X-axis direction to extend toward a rear end of the substrate processing apparatus 1. A pair of wafer loading/unloading ports through which the wafer 18 is loaded into or unloaded out of the sub-housing 16 is provided at a front wall 17 of the sub-housing 16. The pair of wafer loading/unloading ports is arranged vertically in two stages. A pair of pod openers (including the pod opener 14) is provided at the pair of wafer loading/unloading ports (which are openings), respectively. For example, an upper pod opener and a lower pod opener may be provided as the pair of pod openers. Hereinafter, the upper pod opener may also be referred to as an “upper pod opener 14” or the “pod opener 14”, and the lower pod opener may also be referred to as a “lower pod opener 14” or the “pod opener 14”.

A loading port structure 21 configured to transfer the wafer 18 in the pod 9 is provided on the front wall 17. The loading port structure 21 includes a mounting table (which is a placement table) 22 where the pod 9 is placed thereon. By attaching or detaching the lid of the pod 9 placed on the mounting table 22 using the pod opener 14, the wafer 18 can be transferred to and from the pod 9.

The sub-housing 16 defines a transfer chamber 23 fluidically isolated from a space (hereinafter, also referred to as a “pod transfer space”) in which the pod transfer structure 15 or the rotatable pod shelf 11 is provided. A wafer transfer structure (which is a transfer structure) 24 is provided in the transfer chamber 23 (hereinafter, also referred to as a “substrate transfer space”). The wafer transfer structure 24 is configured to transfer (load) the wafer 18 into and to transfer (unload) the wafer 18 out of a boat (which is a substrate retainer) 26.

In the transfer chamber 23, a standby space 27 where the boat 26 is accommodated and in standby is provided, and a process furnace 28 such as a vertical type process furnace is provided above the standby space 27. A process chamber 29 is provided inside the process furnace 28, and a lower end portion of the process chamber 29 is configured as a furnace opening. The furnace opening is opened or closed by a furnace opening shutter. The process furnace 28 serves as an example of a process vessel in which the wafer 18 is processed.

A boat elevator (which is a substrate retainer elevating structure) 32 configured to elevate and lower the boat 26 is provided below the process furnace 28. A seal cap (which is a lid) 34 is horizontally attached to the boat elevator 32. The seal cap 34 is configured such that the boat 26 can be vertically supported by the seal cap 34, and such that the furnace opening can be airtightly closed by the seal cap 34 while the boat 26 is loaded into the process chamber 29.

The boat 26 is configured such that a plurality of wafers (for example, from 50 wafers to 125 wafers) including the wafer 18 are supported on the boat 26 in a horizontal orientation and in a multistage manner with their centers aligned with one another. Further, in the present specification, a notation of a numerical range such as “from 50 wafers to 125 wafers” means that a lower limit and an upper limit are contained in the numerical range. Therefore, for example, a numerical range “from 50 wafers to 125 wafers” means a range equal to or higher than 50 wafers and equal to or less than 125 wafers. The same also applies to other numerical ranges described in the present specification.

A clean air supplier (which is a clean air supply structure or a clean air supply system) 35 is arranged at a location facing the boat elevator 32. The clean air supplier 35 is constituted by a supply fan and a dustproof filter so as to supply clean air such as an inert gas and a clean atmosphere.

As shown in FIG. 1, the substrate processing apparatus 1 includes a controller 100. The controller 100 is configured to be capable of controlling the substrate processing apparatus 1. The controller 100 may be embedded in the substrate processing apparatus 1, or may be provided so as to be capable of accessing to the substrate processing apparatus 1 from an outside of the substrate processing apparatus 1. While the present embodiments will be described by way of an example in which the controller 100 according to the present embodiments is applied to the substrate processing apparatus 1, the controller 100 may control an apparatus other than the substrate processing apparatus 1.

### (2) CONFIGURATION OF LOADING PORT STRUCTURE

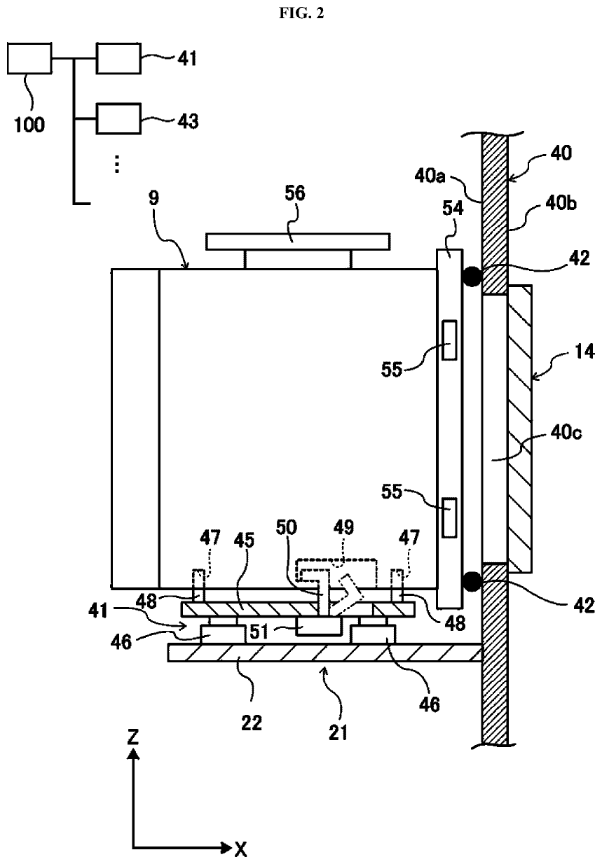

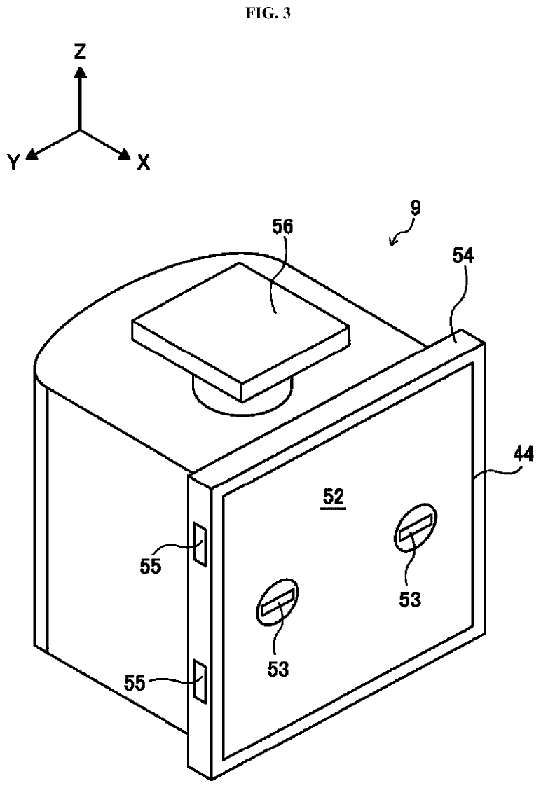

Subsequently, a configuration of the loading port structure 21 will be described. FIG. 2 is a diagram schematically illustrating a vertical cross-section of a locking structure 41 of the loading port structure 21. FIG. 3 is a diagram schematically illustrating an exemplary perspective view of the pod 9. In FIG. 2, in order to explain a configuration of the locking structure 41 of the loading port structure 21, a latching structure 43 (which brings the pod 9 into contact with a frame 40 (which is a part of the front wall 17)) is not illustrated in detail. In addition, the controller 100 is electrically connected to the locking structure 41 and the latching structure 43. That is, the controller 100 is configured to be capable of controlling components of the locking structure 41 and components of the latching structure 43 such that a desired operation can be performed at a desired timing.

For example, the loading port structure 21 includes: the frame 40 constituting a part of the front wall 17 configured to separate an inside and an outside of a local clean environment (also referred to as a “mini environment”); the mounting table 22 whose one end is fixed to the frame 40; the locking structure 41 configured to position the pod 9 placed on the mounting table 22; and the latching structure 43 (described in detail later) configured to press the pod 9 placed on the mounting table 22 against the frame 40.

That is, the frame 40 is configured to separate the transfer chamber 23 (which is the local clean environment) from the pod transfer space (which is outside the local clean environment). For example, the frame 40 includes: a surface 40a serving as a first surface provided adjacent to the pod transfer space; a surface 40b serving as a second surface provided adjacent to the transfer chamber 23; and an opening 40c through which the wafer 18 accommodated in the pod 9 can pass (or can be transferred). The opening 40c may also be referred to as an “entrance”. In other words, the opening 40c through which the wafer 18 can pass is provided in the front wall 17 configured to separate the inside and the outside of the local clean environment.

The mounting table 22 is configured such that the pod 9 can be placed thereon through the pod transfer space.

For example, the locking structure 41 is constituted by: a support table 45 provided on the mounting table 22 and configured such that the pod 9 can be placed thereon; a plurality of guide structures 46 configured to slidably move the support table 45 in the X-axis direction; a plurality of pins 48 respectively fit into a plurality of recesses (concave portions) 47 provided in a bottom surface of the pod 9 so as to position the pod 9 on the support table 45; and an engaging structure 50 configured to be rotated so as to engage with an engagement groove (also referred to as an “engagement recess”) 49 provided in the bottom surface of the pod 9. Hereinafter, each of the plurality of guide structures 46 may also be referred to as a “guide structure 46”.

The engaging structure 50 is configured to be capable of being rotated by a driver (which is a driving structure) 51, and is further configured to be capable of being rotated between a position where the engaging structure 50 engages with the engagement groove 49 and another position where an engagement between the engaging structure 50 and the engagement groove 49 is released. The support table 45 is configured to be movable in a direction substantially perpendicularly (vertically) to the surface 40a as the guide structure 46 moves on the mounting table 22 in the X-axis direction. In a manner described above, the pod 9 placed on the support table 45 of the loading port structure 21 is positioned and fixed on the mounting table 22.

The latching structure 43 is configured such that a flange 54 of the pod 9 placed on the mounting table 22 makes an airtight contact with the frame 40 via a seal 42. In other words, the latching structure 43 is configured such that an opening 44 of the pod 9 placed on the mounting table 22 can make an airtight contact with the surface 40a around the opening 40c.

The pod 9 is configured such that the wafers 18 (for example, 25 wafers) can be accommodated in the pod 9 while being arranged substantially horizontally in a multistage manner. The opening 44 through which the wafer 18 is inserted or removed (that is, loaded or unloaded) is provided in a first end surface of the pod 9, and a lid 52 corresponding to the opening 44 is attached to the opening 44 such that the lid 52 can be attached to or detached from the opening 44. As shown in FIG. 3, for example, the lid 52 is provided with two keyholes 53. By locking or unlocking the keyholes 53 with the pod opener 14, the lid 52 can be attached to or detached from the opening 44. An inside (inner portion) of the pod 9 is configured to be substantially airtight by the lid 52.

The flange 54 protruding from each peripheral surface of the pod 9 toward an outer periphery thereof is provided around the opening 44 of the pod 9. For example, two recesses 55 are provided on each of side surfaces of the flange 54 with a predetermined interval therebetween in the Z-axis direction. Hereinafter, each of the recesses 55 may also be referred to as a “recess 55”. A space (which resembles an inverted truncated pyramid) is provided inside the recess 55. Thereby, a side surface of the recess 55 is slightly inclined rather than perpendicular to a depth direction. The recesses 55 are not limited to such a configuration where they are provided at two locations on each side surface of the flange 54. For example, instead of the two recesses 55, one or more recesses may be provided at one or more locations on each side surface of the flange 54. In addition, the flange 54 may be configured as a lattice-like rib structure protruding outward, and each of the recesses 55 may correspond to one of concave portions interposed between ribs of the lattice-like rib structure.

In addition, a handle (which is of a flange shape) 56 capable of being gripped by a transfer robot is provided on an upper surface of the pod 9.

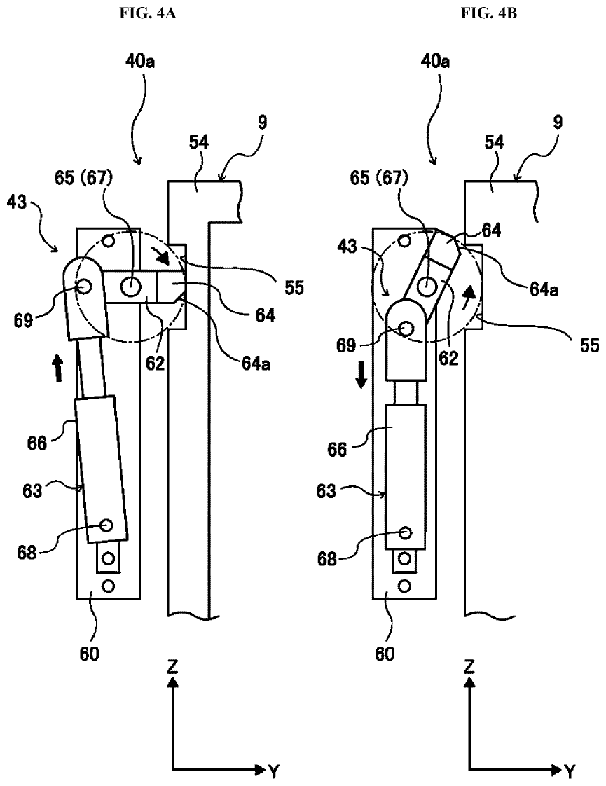

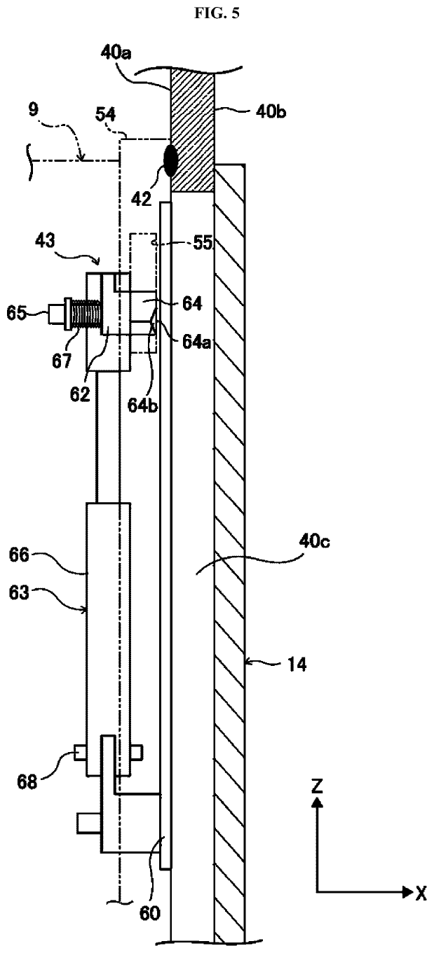

Subsequently, a configuration of the latching structure 43 will be described. FIG. 4A is a diagram schematically illustrating a state in which the pod 9 is fixed to the surface 40a of the frame 40 by the latching structure 43. FIG. 4B is a diagram schematically illustrating a state in which the pod 9 is released from the surface 40a of the frame 40 by the latching structure 43. FIG. 5 is a diagram schematically illustrating the latching structure 43 when viewed along the Y-axis direction of FIG. 4A. In addition, in FIG. 5, the pod 9 is shown by a two-dot chain line to explain the latching structure 43 in detail.

The latching structure 43 is fixed to the surface 40a of the frame 40 by a support (which is a support structure) 60 of a plate shape. That is, the latching structure 43 is provided at the surface 40a outside the local clean environment, and not adjacent to other surfaces of the frame 40 than the surface 40a. Therefore, the latching structure 43 can be arranged not to interfere with components such as the pod opener 14 and a mapping sensor, and can be easily attached to the substrate processing apparatus 1.

For example, the latching structure 43 includes: a pair of heads 62 respectively engaging with at least two recesses 55 formed on each side surface of the flange 54; and a pair of drivers (driving structures) 63 configured to respectively drive the pair of heads 62 to move in a direction substantially parallel to the surface 40a. Configurations of the pair of heads 62 are substantially the same with each other and configurations of the pair of drivers 63 are substantially the same with each other. In addition, the pair of heads 62 (and the pair of drivers 63) is arranged symmetrically with respect to a plane and is located at positions facing each other with the opening 40c of the surface 40a interposed therebetween. Hereinafter, each of the pair of heads 62 may also be referred to as a “head 62”, and each of the pair of drivers 63 may also be referred to as a “driver 63”. Therefore, in the following description, the present embodiments will be described using the head 62 and the driver 63 engaging with the recess 55 provided on each side surface of the pod 9.

The head 62 is provided with a contact portion 64 at one end thereof. The contact portion 64 comes into contact with the side surface of the recess 55 and generates a force of pressing the flange 54 against the surface 40a. The contact portion 64 is provided with a first tapered surface 64a inclined relative to a direction along which the pod 9 moves to a docking position at which the pod 9 is pressed against the surface 40a. A pivot 65 is inserted into an axial hole provided at approximately a center of the head 62, and the head 62 is provided so as to be rotatable around the pivot 65. The pivot 65 is fixed to the support 60 so as to be substantially perpendicular to the surface 40a. The contact portion 64 is provided with the first tapered surface 64a and a second tapered surface 64b. The first tapered surface 64a is chamfered with a surface substantially perpendicular to the surface 40a at a corner (front end) of the contact portion 64 that comes into the earliest contact with the flange 54 when the head 62 is rotated. The second tapered surface 64b is chamfered with a surface slightly inclined with respect to the surface 40a. A tilt (inclination) of this surface is set such that it moves away from the surface 40a as it approaches the front end of the head 62. For example, an angle of the surface is set within a range from 1° to 40°.

Here, a position where the pod 9 is pressed against the surface 40a by a movement of the guide structure 46 in the loading port structure 21 may also be referred to as the “docking position”, and a position where the pod 9 is separated from the surface 40a may also be referred to as an “undocking position”.

For example, the driver 63 is constituted by: a cylinder 66 capable of expanding and contracting on a plane substantially parallel to the flange 54 to be locked (or latched) with; and a bias structure 67 configured to bias the head 62 toward the surface 40a. As the cylinder 66, for example, an air cylinder capable of expanding and contracting due to a change in an air pressure may be used. In addition, as the bias structure 67, for example, a coil spring capable of being arranged along an outer periphery of the pivot 65 may be used. Thereby, the latching structure 43 can directly set an appropriate pressing force capable of maintaining the pod 9 airtight without interfering with a smooth locking operation (latching operation).

The cylinder 66 is rotatably fixed to the support 60 by a pin 68 provided on one end (first end) of the cylinder 66. In addition, the cylinder 66 rotatably supports the head 62 by a pin 69 provided on the other end (second end) of the cylinder 66 and opposite to the pin 68. That is, the cylinder 66 is configured to move in a direction without a component in the X-axis direction, to expand and contract substantially horizontally with respect to the surface 40a. Further, the cylinder 66 is rotated with respect to the support 60 by the pin 68, and the cylinder 66 is further configured to rotate the head 62 by the pin 69.

The latching structure 43 is configured to be capable of being switched between an engaged state in which the latching structure 43 engages with the recess 55 of the flange 54 as shown in FIG. 4A and a disengaged state in which the latching structure 43 does not engage with the recess 55 of the flange 54 so that a movement of the pod 9 is unrestricted in the X-axis direction, the Y-axis direction, and the Z-axis direction as shown in FIG. 4B.

A maximum length of the latching structure 43 in the Y-axis direction (also referred to as a “width of the latching structure 43”) is set to a length that does not interfere with the pod 9 when the pod 9 is transferred to the loading port structure 21, for example, 45 mm or less. In addition, a maximum length of the latching structure 43 in the X-axis direction from the surface 40a (also referred to as a “thickness protruding from the surface 40a”) is set to a length that does not interfere with the pod 9 when the pod 9 is transferred to the loading port structure 21, and is set to be smaller than a distance between the flange 54 and the surface 40a at the undocking position where the locking structure 41 is released and the pod 9 is separated from the surface 40a.

The head 62 is rotated about the pivot 65 by the driver 63. More specifically, the pair of heads 62 is rotated by the pair of drivers 63. Thereby, the first tapered surface 64a of the contact portion 64 slides on the flange 54 when the head 62 moves to the docking position. As a result, the head 62 is pushed in a direction opposite to a direction along which the flange 54 is pressed.

The pair of heads 62 is configured to transition the latching structure 43 between the engaged state and the disengaged state mentioned above by the pair of drivers 63 in a synchronized manner with an accuracy enough to prevent a positional deviation in the Y-axis direction of the pod 9. The pair of heads 62 generates the force of pressing the flange 54 against the surface 40a by transitioning the latching structure 43 from the disengaged state to the engaged state.

For example, in the loading port structure 21, when the lid 52 of the pod 9 is opened, an oxygen concentration in the transfer chamber 23 increases. Therefore, when the wafer 18 is being transferred, a supply of the inert gas into the transfer chamber 23 is increased to exhaust oxygen. As a result, a pressure (inner pressure) of the transfer chamber 23, which is inside the local clean environment, is 200 Pa or more higher than the outside of the local clean environment, and the pod 9 may come off the loading port structure 21 when the lid 52 of the pod 9 is opened. In addition, when the pod 9 comes off the loading port structure 21, a gap may be created. As a result, an atmosphere inside and outside the local clean environment may leak. According to the embodiments of the present disclosure, by contacting an upper side surface of the pod 9 with the frame 40 (which is part of the front wall 17) in addition to the bottom surface of the pod 9, when the lid 52 of the pod 9 is opened, it is possible to prevent a tilt of the pod 9 in the X-axis direction, the Y-axis direction and the Z-axis direction from occurring even when the pressure inside the local clean environment is 200 Pa or more higher than the pressure outside the local clean environment.

### (3) SUBSTRATE PROCESSING

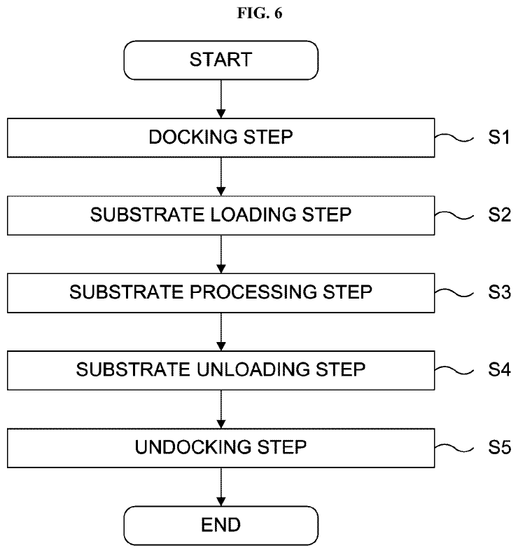

Subsequently, as a part of a manufacturing process of a semiconductor, a substrate processing of processing the wafer 18 by using the substrate processing apparatus 1 mentioned above will be described with reference to FIG. 6. In the following description, operations of components constituting the substrate processing apparatus 1 are controlled by the controller 100.

First, when the pod 9 is transferred to the pod transfer table 8, the pod loading/unloading port is opened by the front shutter 7. Then, the pod 9 placed on the pod transfer table 8 is transferred (loaded) into the housing 2 by the pod transfer structure 15, and is placed on the rotatable pod shelf 11.

The pod 9 is temporarily stored in the rotatable pod shelf 11. Then, the pod 9 is transferred to one of the pod openers 14 (that is, one of the upper pod opener 14 and the lower pod opener 14) and then to the loading port structure 21 by the pod transfer structure 15. Alternatively, the pod 9 may be transferred directly from the pod transfer table 8 to the loading port structure 21. When the pod 9 is being transferred, the opening 40c is closed by the pod opener 14, and the transfer chamber 23 is supplied with and filled with the clean air.

### <Docking Step S1>

After the pod 9 is transferred to the loading port structure 21, the pod 9 is docked by pressing an end surface of the flange 54 (that is, the end surface of the flange 54 adjacent to the opening 44) against the surface 40a of an edge of the opening 40c of the frame 40 by the locking structure 41 and the latching structure 43. Then, the lid 52 is detached by the pod opener 14, and the opening 44 is opened to communicate with a local clean space (that is, the local clean environment).

### <Substrate Loading Step S2>

The wafer 18 is taken out from the pod 9 by the wafer transfer structure 24. Then, the wafer 18 is aligned by a notch aligner (not shown). Then, by the wafer transfer structure 24, the wafer 18 is transferred (or loaded) into the standby space 27 provided in a rear region of the transfer chamber 23, and loaded (or charged) into the boat 26.

After the wafer 18 is charged into the boat 26, the wafer transfer structure 24 then returns to the pod 9 and transfers a subsequent wafer among the wafers 18 from the pod 9 into the boat 26. When a predetermined number of wafers among the wafers 18 are charged into the boat 26, the furnace opening of the process furnace 28 closed by the furnace opening shutter is opened. Subsequently, the boat 26 is elevated by the boat elevator 32 such that the boat 26 is loaded (inserted) into the process chamber 29, and the furnace opening is airtightly closed by the seal cap 34.

### <Substrate Processing Step S3>

The process chamber 29 is supplied with the inert gas and is vacuum-exhausted such that a pressure (inner pressure) of the process chamber 29 reaches and is maintained at a desired pressure. In addition, the process chamber 29 is heated to a predetermined temperature such that a desired temperature distribution in the process chamber 29 can be obtained.

Then, a process gas whose flow rate is controlled to a predetermined flow rate is supplied by a gas supply structure (which is a gas supplier or a gas supply system) (not shown), and the process gas comes into contact with a surface of the wafer 18 while flowing through the process chamber 29. Thereby, a predetermined processing is performed on the surface of the wafer 18. Further, the process gas after a reaction of the predetermined processing is exhausted from the process chamber 29 by a gas exhaust structure (which is a gas exhauster or a gas exhaust system) (not shown). In the present disclosure, the term “process gas” refers to a gas (or gases) supplied into the process chamber 29. The same also applies to the following description.

After a predetermined process time has elapsed, the inert gas is supplied through the gas supply structure, an inner atmosphere of the process chamber 29 is replaced with the inert gas, and the inner pressure of the process chamber 29 is returned to the normal pressure. In the present specification, the term “process time” refers to a time duration of continuously performing a process related thereto. The same also applies to the following description.

### <Substrate Unloading Step S4>

The boat 26 is lowered by the boat elevator 32 through the seal cap 34. The wafers 18 (which are processed) are unloaded out of the boat 26 in an order reverse to that of loading the wafers 18 into the boat 26 as described above, and then accommodated in the pod 9 of the loading port structure 21.

<Undocking step S5>

The opening 44 of the pod 9 accommodating the wafers 18 is closed (or sealed) with the lid 52 by the pod opener 14, and the pod 9 is undocked by releasing a contact between the pod 9 and the surface 40a of the edge of the opening 40c by the locking structure 41 and the latching structure 43.

Then, the pod 9 accommodating the wafers 18 (which are processed) is unloaded out of the substrate processing apparatus 1 in an order reverse to that of loading the pod 9 as described above.

### (4) OTHER EMBODIMENTS (MODIFIED EXAMPLES)

Subsequently, modified examples of the latching structure 43 in the embodiments mentioned above will be described in detail. In the following modified examples, portions (features) different from those of the embodiments mentioned above will be described in detail.

### First Modified Example

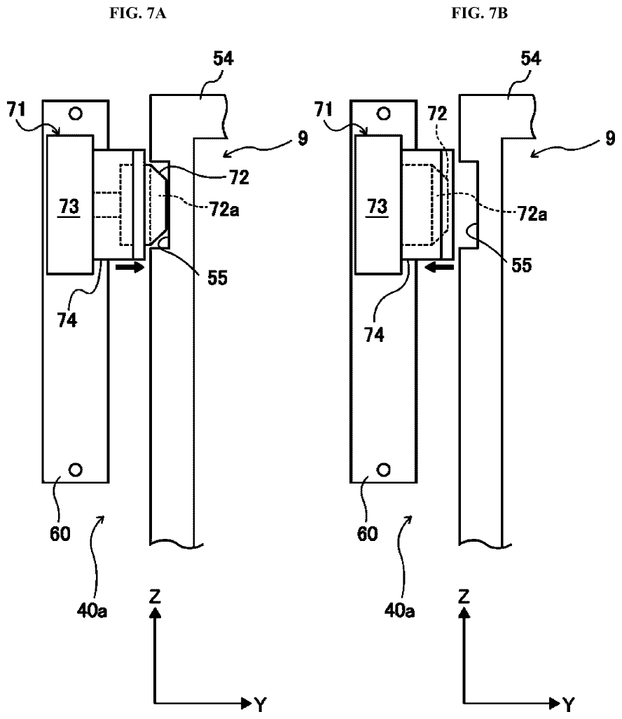

FIG. 7A is a diagram schematically illustrating a state in which the pod 9 is fixed to the surface 40a of the frame 40 by a latching structure 71 according to the present modified example. FIG. 7B is a diagram schematically illustrating a state in which the pod 9 is released from the surface 40a of the frame 40 by the latching structure 71.

For example, the latching structure 71 includes: a pair of heads 72 configured to respectively come into contact with at least two recesses 55 formed on each side surface of the flange 54; a pair of drivers (driving structures) 73 configured to respectively drive the pair of heads 72 to linearly move in the Y-axis direction, that is, in the direction substantially parallel to the surface 40a; and a guide structure 74 configured to guide a linear movement of the pair of heads 72. Hereinafter, each of the pair of heads 72 may also be referred to as a “head 72”, and each of the pair of drivers 73 may also be referred to as a “driver 73”. At a tip (front end) of the head 72, a tapered surface 72a is provided. The tapered surface 72a is inclined such that a distance from the surface 40a increases as it approaches the tip (front end) of head 72. The driver 73 and the guide structure 74 are fixed to the support 60. As the driver 73, for example, an air cylinder capable of moving the head 72 in the Y-axis direction due to a change in an air pressure may be used. The pair of heads 72 is configured to press the flange 54 from both sides by the pair of drivers 73, respectively, in a synchronized manner with an accuracy enough to prevent the positional deviation in the Y-axis direction of the pod 9.

That is, the latching structure 71 is configured to be movable in a direction substantially parallel to the surface 40a, and is further configured such that the pair of heads 72 respectively comes into contact with the recesses 55 of the flange 54 to press the pod 9 from both sides without generating the force of pressing the flange 54 against the surface 40a.

According to the present modified example, it is possible to obtain substantially the same effects as those of the embodiments mentioned above. In addition, it is possible to easily set the pressing force such that the pod 9 is contacted while suppressing a deformation of the pod 9. It is also possible to reduce a vibration occurring when the pod 9 is docked.

### Second Modified Example

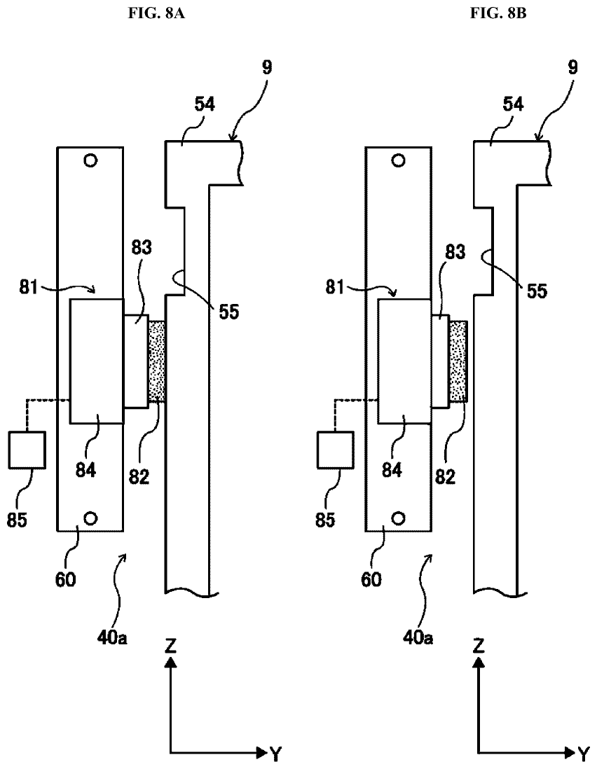

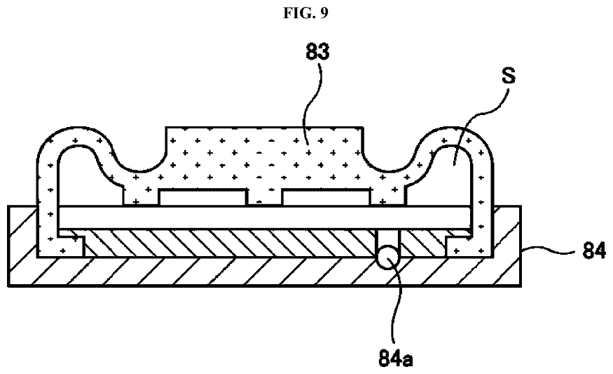

FIG. 8A is a diagram schematically illustrating a state in which the pod 9 is fixed to the surface 40a of the frame 40 by a latching structure 81 according to the present modified example. FIG. 8B is a diagram schematically illustrating a state in which the pod 9 is released from the surface 40a of the frame 40 by the latching structure 81. FIG. 9 is a diagram schematically illustrating a vertical cross-section of a diaphragm among a pair of diaphragms 83 constituting the latching structure 81.

For example, the latching structure 81 includes: a pair of heads 82 configured to respectively come into contact with each side surface of the flange 54; the pair of diaphragms 83 configured to respectively drive the pair of heads 82 in the Y-axis direction by a working fluid; a pair of housings 84 configured to respectively hold (or support) the pair of diaphragms 83 and configured such that the working fluid can be supplied into each of the pair of housings 84; and a pair of regulators 85 configured to communicate with an inside (inner portion) of each of the pair of the housings 84 via a piping and configured to adjust a pressure of the working fluid. Hereinafter, each of the pair of heads 82 may also be referred to as a “head 82”, each of the pair of diaphragms 83 may also be referred to as a “diaphragm 83”, each of the pair of housings 84 may also be referred to as a “housing 84”, and each of the pair of regulators 85 may also be referred to as a “regulator 85”. Configurations of the pair of heads 82 are substantially the same with each other, configurations of the pair of diaphragms 83 are substantially the same, with each other and configurations of the pair of housings 84 are substantially the same with each other. In addition, the pair of heads 82 (the pair of diaphragms 83 and the pair of housings 84) is arranged symmetrically with respect to a line at positions facing each other with the opening 40c of the surface 40a interposed therebetween. Therefore, in the following description, the present modified example will be described using the head 82, the diaphragm 83 and the housing 84 which come into contact with the flange 54 on the side surface of the pod 9.

As shown in FIG. 9, a working fluid supply passage 84a is provided in the housing 84. The working fluid supplied through the regulator 85 is filled in the diaphragm 83. For example, the diaphragm 83 is made of an elastic material such as polyurethane. In addition, a space S is provided inside the diaphragm 83. The working fluid is filled in the space S. On the other hand, for example, the head 82 is made of a resin (such as polyamide) which is abrasion-resistant and self-lubricating.

The regulator 85 is configured to set a force with which the head 82 presses the flange 54 to a predetermined value. The regulator 85 may include a three-way valve configured to switch between supplying and discharging the working fluid whose pressure is regulated. By changing the pressure of the working fluid in the head 82 via the diaphragm 83 by using the regulator 85, it is possible to move the head 82 in the Y-axis direction. For example, the diaphragm 83 and the housing 84 are commercially available as a clamp module, and may also be referred to as a “diaphragm type actuator”.

That is, by increasing the pressure of the working fluid in the space S by using the pair of regulators 85, the pair of heads 82 is moved in a direction to come into contact with the flange 54, and the pair of heads 82 presses the flange 54 from both sides. In addition, by decreasing the pressure of the working fluid in the space S by using the pair of regulators 85, the pair of heads 82 is moved in a direction away from the flange 54. The latching structure 81 is configured such that, even when the pod 9 without the recess 55 is used, the pair of heads 82 comes into contact with the flange 54 to press the pod 9 from both sides due to a flexibility of the diaphragm 83.

According to the present modified example, it is possible to obtain substantially the same effects as those of the embodiments mentioned above. In addition, according to the present modified example, by using the diaphragm type actuator mentioned above, the head 82 can come into contact with the flange 54 in accordance with a shape of the flange 54. In other words, the head 82 can be used with respect to a variety of types of the pods 9 to be contacted. In addition, by using the diaphragm type actuator, it is possible to prevent an air leakage and a dust generation.

### Third Modified Example

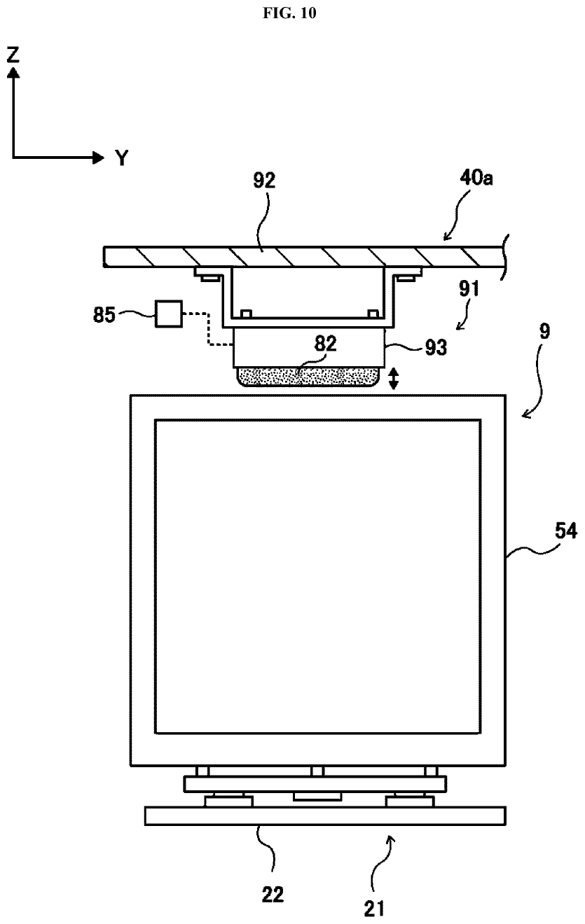

FIG. 10 is a diagram schematically illustrating a latching structure 91 according to the present modified example. In FIG. 10, in order to explain a configuration of the latching structure 91, the handle 56 provided on the upper surface of the pod 9 is not illustrated. For example, the latching structure 91 is constituted by: a head 82 configured to come into contact with an upper surface of the flange 54; a driver (driving structure) 93 configured to drive the head 82 in the up-down direction by a working fluid; and a regulator 85 configured to set the force with which the head 82 presses the flange 54 to a predetermined value by adjusting a pressure of the working fluid of the driver 93. By changing the pressure of the working fluid in the head 82 via the driver 93 by using the regulator 85, it is possible to move the head 82 in the Z-axis direction and in a Z-axis direction opposite to the Z-axis direction.

The latching structure 91 is provided at a support 92 provided on the surface 40a above the opening 40c of the frame 40. In other words, when the pod 9 is placed on the loading port structure 21, the latching structure 91 is disposed above the flange 54 of the pod 9.

The latching structure 91 is configured to increase the pressure of the working fluid of the driver 93 by using the regulator 85. Thereby, it is possible to move the head 82 in the −Z-axis direction (which is a direction toward the flange 54) such that the head 82 comes into contact with the flange 54. In addition, the latching structure 91 is further configured to decrease the pressure of the working fluid of the driver 93 by using the regulator 85. Thereby, it is possible to move the head 82 in the Z-axis direction (which is a direction away from the flange 54) such that a contact between the head 82 and the flange 54 is released. In other words, the latching structure 91 is configured to be capable of linearly moving the head 82 in the Z-axis direction (also referred to as the “up-down direction”).

According to the present modified example, it is possible to obtain substantially the same effects as those of the embodiments mentioned above. In addition, according to the present modified example, by using the diaphragm type actuator mentioned above, the head 82 can come into contact with the flange 54 in accordance with the shape of the flange 54. In addition, by using the diaphragm type actuator, it is possible to prevent the air leakage and the dust generation. Further, since the vibration occurring when the pod 9 is docked or undocked can be reduced, it is possible to smoothly perform the operations.

### Fourth Modified Example

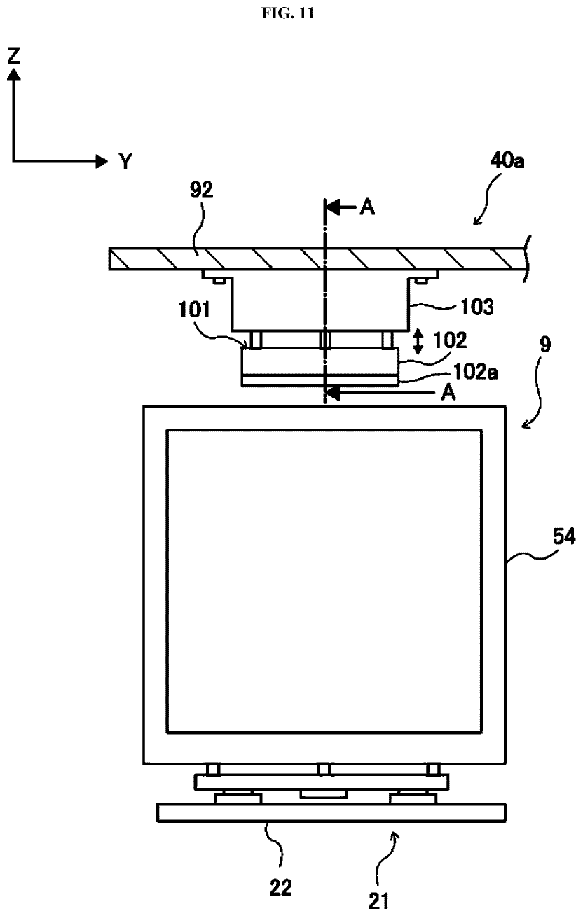

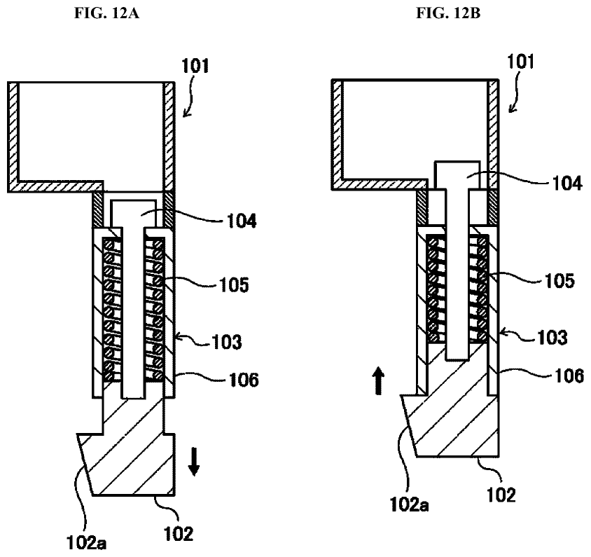

FIG. 11 is a diagram schematically illustrating a latching structure 101 according to the present modified example. In FIG. 11, in order to explain a configuration of the latching structure 101, the handle 56 provided on the upper surface of the pod 9 is not illustrated. FIG. 12A is a diagram schematically illustrating a cross-section of the latching structure 101, taken along a line A-A shown in FIG. 11, when the latching structure 101 is in contact with the flange 54, and FIG. 12B is a diagram schematically illustrating the cross-section of the latching structure 101, taken along the line A-A shown in FIG. 11, when the latching structure 101 is released from contact with the flange 54.

Similar to the third modified example mentioned above, the latching structure 101 is provided at the support 92 provided on the surface 40a above the opening 40c of the frame 40. In other words, when the pod 9 is placed on the loading port structure 21, the latching structure 101 is disposed above the flange 54 of the pod 9.

For example, the latching structure 101 is constituted by: a head 102 configured to come into contact with the upper surface of the flange 54; and a linear mover (which is a linear moving structure) 103 configured to support the head 102 such that the head 102 can make a linear movement in the Z-axis direction. For example, the linear mover 103 includes: a housing 106; a bias structure 105 configured to bias the head 102 toward the flange 54 inside the housing 106; and a support 104 whose one end (first end) is disposed outside the housing 106 and whose the other end (second end) is connected to the head 102. The bias structure 105 is provided around the support 104 inside the housing 106, and the bias structure 105 and the support 104 are provided in a coaxial manner. For example, the bias structure 105 is configured as a compression coil spring, and the latching structure 101 is configured to come into contact with and to press the head 102 against the flange 54 by using a restoring force of the bias structure 105 alone. A tapered surface 102a is provided at the head 102 to push the head 102 upward while being rubbed against an edge of the flange 54 when the pod 9 is moved from the undocking position to the docking position. A length of the head 102 in the Y-axis direction in the present modified example is set to be sufficiently greater than a distance between ribs of the flange 54 in the Y-axis direction. Thereby, the head 102 can slide smoothly along ridges of the ribs without getting caught in recesses between the ribs.

According to the present modified example, it is possible to obtain substantially the same effects as those of the embodiments mentioned above. In addition, according to the present modified example, by further using the bias structure 105 with different biasing forces, it is possible to easily set the pressing force such that the pod 9 is contacted while suppressing the deformation of the pod 9.

The configurations of the locking structure 41, the latching structures and the pod 9 described in the embodiments or the modified examples mentioned above are merely examples, and may be modified in accordance with circumstances without departing from the scope of the technique of the present disclosure.

Further, the process flow described in the embodiments mentioned above is merely an example, and a redundant step may be deleted, a new step may be added or process procedures may be changed, without departing from the scope of the technique of the present disclosure.

Further, in addition to or instead of a substrate processing apparatus capable of manufacturing a semiconductor device, the technique of the present disclosure may also be applied to other substrate processing apparatuses such as an LCD (Liquid Crystal Display) manufacturing apparatus capable of processing a glass substrate. The contents of the substrate processing may include not only a film forming process of forming a film such as a CVD (Chemical Vapor Deposition) film, a PVD (Physical Vapor Deposition) film, an epitaxial growth film, an oxide film, a nitride film and a metal-containing film, but also a process such as an annealing process, an oxidation process, a diffusion process, an etching process, an exposure process, a photolithography process, a coating process, a molding process, a developing process, a dicing process, a wire bonding process and an inspection process.

For example, the embodiments mentioned above are described by way of an example in which a vertical type (batch type) substrate processing apparatus capable of simultaneously processing a plurality of substrates is used to process the substrate. However, the technique of the present disclosure is not limited thereto. For example, the technique of the present disclosure may be preferably applied when a single wafer type substrate processing apparatus capable of processing one or several substrates at a time is used to process the substrate. For example, the embodiments mentioned above are described by way of an example in which a substrate processing apparatus including a hot wall type process furnace is used to process the substrate. However, the technique of the present disclosure is not limited thereto. For example, the technique of the present disclosure may be preferably applied when a substrate processing apparatus including a cold wall type process furnace is used to process the substrate.

The process procedures and the process conditions of each process using the substrate processing apparatuses exemplified above may be substantially the same as those of the embodiments or modified examples mentioned above. Even in such a case, it is possible to obtain substantially the same effects as in the embodiments or the modified examples mentioned above.

For example, the technique of the present disclosure may also be applied when the embodiments and the modified examples mentioned above are appropriately combined. For example, the process procedures and the process conditions of each process of such a combination may be substantially the same as those of the embodiments or the modified examples mentioned above.

According to some embodiments of the present disclosure, it is possible to suppress the tilt of the substrate container when the lid of the substrate container is opened.

What is claimed is:

1. A loading port structure comprising:
a frame constituting a part of a wall configured to separate an inside and an outside of a local clean environment, and comprising:
a first surface provided outside the local clean environment and configured to be capable of making an airtight contact with an opening of a substrate container; and
an entrance through which a substrate accommodated in the substrate container is capable of passing; and
a latching structure provided adjacent to the first surface and configured to be capable of being switched between an engaged state in which the latching structure engages with a flange provided around the opening and a disengaged state in which the latching structure does not engage with the flange so that a movement of the substrate container is unrestricted in an up-down direction and in a front-rear direction,
wherein the latching structure comprises:
a pair of heads configured to respectively engage with at least two recesses formed on each side of the flange; and
a pair of drivers configured to respectively move the pair of heads in a direction substantially parallel to the first surface,
wherein each of the pair of heads is provided with a contact portion configured to generate a force of pressing the flange against the first surface by transitioning the latching structure from the disengaged state to the engaged state, and
wherein the contact portion comprises a tapered surface.

2. A loading port structure comprising:
a frame constituting a part of a wall configured to separate an inside and an outside of a local clean environment, and comprising:
a first surface provided outside the local clean environment and configured to be capable of making an airtight contact with an opening of a substrate container; and
an entrance through which a substrate accommodated in the substrate container is capable of passing;
a locking structure configured to engage with an engagement groove provided in a bottom surface of the substrate container; and
a latching structure provided adjacent to the first surface and configured to be movable in a direction substantially parallel to the first surface,
wherein the latching structure is further configured to come into contact with a flange provided around the opening and to press the substrate container from both sides thereof or an upper surface thereof without generating a force of pressing the flange against the first surface.

3. The loading port structure of claim 1, wherein the latching structure is not adjacent to other surfaces of the frame than the first surface.

4. The loading port structure of claim 1, wherein the latching structure is further configured to prevent the substrate container from tilting in the front-rear direction even when a pressure inside the local clean environment is 200 Pa or more higher than a pressure outside the local clean environment.

5. The loading port structure of claim 2, wherein the latching structure is further configured to prevent the substrate container from tilting in the front-rear direction even when a pressure inside the local clean environment is 200 Pa or more higher than a pressure outside the local clean environment.

6. The loading port structure of claim 1, further comprising
a support table on which the substrate container is placed, and configured to be movable in a direction substantially perpendicular to the first surface.

7. The loading port structure of claim 1, wherein a thickness of the latching structure protruding from the first surface is set to be smaller than a distance between the flange and the first surface at an undocking position where the substrate container is separated from the first surface.

8. The loading port structure of claim 2, wherein a thickness of the latching structure protruding from the first surface is set to be smaller than a distance between the flange and the first surface at an undocking position where the substrate container is separated from the first surface.

9. The loading port structure of claim 1, wherein each of the pair of heads is configured to transition the latching structure between the engaged state and the disengaged state in a synchronized manner with an accuracy enough to prevent a positional deviation in a left-right direction of the substrate container.

10. The loading port structure of claim 1, wherein the pair of drivers are configured to respectively move the pair of heads in a direction without a component in the front-rear direction.

11. The loading port structure of claim 1, wherein each of the pair of heads is supported rotatably and movably in a rotational axis direction, and
wherein each of the pair of drivers comprises:
a cylinder configured to expand and contract substantially parallel to the flange to be locked with; and
a bias structure configured to bias each of the pair of heads in the rotational axis direction.

12. The loading port structure of claim 1, wherein a width of each of the pair of heads is set to 45 mm or less.

13. The loading port structure of claim 2, wherein the latching structure comprises:
a head configured to come into contact with the flange; and
a bias structure configured to support the head such that the head is capable of making a linear movement, and
wherein the latching structure is further configured to press the head against the flange by using a restoring force of the bias structure alone.

14. The loading port structure of claim 12, wherein each of the pair of heads is provided with a tapered surface inclined relative to a direction along which the substrate container moves to a docking position at which the substrate container is pressed against the first surface, and
wherein the tapered surface is configured to slide on the flange when the substrate container moves to the docking position such that each head is pushed in a direction opposite to a direction along which the flange is pressed.

15. The loading port structure of claim 2, wherein the latching structure comprises:
a head provided above the entrance and configured to come into contact with the flange provided on an upper surface of the substrate container;
an actuator configured to drive the head in an up-down direction by a working fluid; and
a regulator configured to set the a force with which the head presses the flange to a predetermined value by adjusting a pressure of the working fluid of the actuator.

16. The loading port structure of claim 2, wherein the latching structure comprises:
a head configured to come in contact with the flange; and
a diaphragm type actuator configured to move the head,
wherein the head is attached to the diaphragm type actuator such that the head is movable in a direction opposite to a movement direction thereof.

17. A substrate processing apparatus comprising
the loading port structure of claim 1.

18. A substrate processing apparatus comprising
the loading port structure of claim 2.

19. A substrate processing method comprising:
(a) bringing an opening of a substrate container into an airtight contact with a first surface of a frame, wherein the frame constitutes a part of a wall configured to separate an inside and an outside of a local clean environment and is provided with an entrance through which a substrate accommodated in the substrate container is capable of passing, and wherein the first surface is provided outside the local clean environment;
(b) switching a latching structure between an engaged state in which the latching structure engages with a flange provided around the opening and a disengaged state in which the latching structure does not engage with the flange so that a movement of the substrate container is unrestricted in an up-down direction and in a front-rear direction, wherein the latching structure is provided adjacent to the first surface and comprises:
a pair of heads configured to respectively engage with at least two recesses formed on each side of the flange; and
a pair of drivers configured to respectively move the pair of heads in a direction substantially parallel to the first surface; and
(c) processing the substrate taken out from the substrate container through the opening,
wherein, in (b), a contact portion in each of the pair of heads is configured to generate a force of pressing the flange against the first surface by transitioning the latching structure from the disengaged state to the engaged state, and
wherein the contact portion comprises a tapered surface.

20. A method of manufacturing a semiconductor device, comprising
the substrate processing method of claim 19.
